(19) United States
(12) Patent Application Publication
(10) Pub. No.: US 2017/0170420 A1
(43) Pub. Date: Jun. 15, 2017

(54) ORGANIC ELECTROLUMINESCENCE DEVICE

(71) Applicant: CANON KABUSHIKI KAISHA, Tokyo (JP)

(72) Inventor: Takayuki Ito, Kawasaki-shi (JP)

(21) Appl. No.: 15/373,326

(22) Filed: Dec. 8, 2016

(30) Foreign Application Priority Data
Dec. 10, 2015 (JP) 2015-240722

(51) Int. Cl. B32B 19/00

(52) U.S. Cl. CPC H01L 51/5092; H01L 51/0067; H01L 51/0056; H01L 51/0055; H01L 51/0058; H01L 51/006; H01L 51/0072; G03G 15/04063; H01L 51/5237

(57) ABSTRACT

This disclosure provides an organic electroluminescence device having an anode, a cathode, and an organic compound layer which is disposed between the anode and the cathode and has a light-emitting layer and an organic functional layer, in which the organic functional layer contains an organic compound represented by the following general formula (1) or (2) and a transition metal having a work function of 4.4 eV or more,

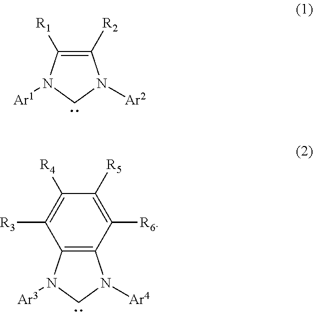

### BACKGROUND OF THE INVENTION

Field of the Invention

The present disclosure relates to an organic electroluminescence device.

Description of the Related Art

In recent years, in contrast to electronic functional elements fabricated using inorganic compounds, organic electronic devices fabricated using organic compounds capable of utilizing coating film formation and a low-temperature process which have been difficult to be applied to inorganic compounds have drawn attention and have been examined. In particular, among the organic electronic devices, the development of an organic electroluminescence device (organic EL device) has been rapidly advanced. Moreover, the development of electronic devices having the organic electroluminescence device has also been performed so far. For example, in display devices in which the organic electroluminescence device is installed in various information processing devices, a demand for a reduction in power consumption of the organic electroluminescence device has grown. In order to achieve the power consumption reduction, a voltage reduction of the organic electroluminescence device has been attempted.

U.S. Pat. No. 6,013,384 describes reducing the voltage of an organic electroluminescence device by co-depositing an organic compound and a low work function metal, such as alkali metal. International Publication No. WO2005/086251 describes reducing the voltage of an organic electroluminescence device by doping a metal complex (organic n-dopant) into an organic semiconductor. Furthermore, Japanese Patent Laid-Open No. 2012-256882 describes reducing the voltage of an organic electroluminescence device by doping a carbene compound (organic n-dopant) into an electron transport material.

However, the alkali metal and the organic n-dopant described in U.S. Pat. No. 6,013,384, International Publication No. WO2005/086251, and Japanese Patent Laid-Open No. 2012-256882 have strong reducing properties due to the characteristics thereof and have a property of easily reacting with moisture or oxygen, and therefore are difficult to be handled in the atmosphere. Therefore, the device life of the organic electroluminescence devices described in U.S. Pat. No. 6,013,384, International Publication No. WO2005/086251, and Japanese Patent Laid-Open No. 2012-256882 has not been sufficient.

On the other hand, some organic n-dopants have been stable in the atmosphere. However, the organic n-dopants stable in the atmosphere have had a low donor property and insufficient electron injection efficiency.

### SUMMARY OF THE INVENTION

It is an aspect of the present disclosure to provide an organic electroluminescence device which is driven at a low voltage and has a long life.

An example embodiment of an organic electroluminescence device has an anode, a cathode, and an organic compound layer which is disposed between the anode and the cathode and has a light-emitting layer and an organic functional layer,

in which the organic functional layer contains an organic compound represented by the following general formula (1) or (2) and a transition metal having a work function of 4.4 eV or more,

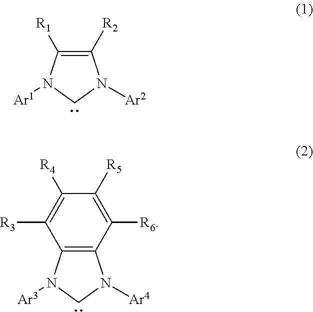

In Formula (1), R₁ and R₂ are each independently selected from the group consisting of a hydrogen atom, a halogen atom, an alkyl group having carbon atoms of 1 or more and 8 or less, and a substituted or unsubstituted aryl group, and Ar¹ and Ar² are each independently selected from the group consisting of a substituted or unsubstituted aromatic hydrocarbon group and a substituted or un substituted heterocyclic group, in case where the aromatic hydrocarbon group and the heterocyclic group are substituted, the substituent is selected from the group consisting of an alkyl group, a halogen atom, and a substituted amino group. In Formula (2), R₃ to R₆ are each independently selected from the group consisting of a hydrogen atom, a halogen atom, an alkyl group having carbon atoms of 1 or more and 8 or less, and a substituted or unsubstituted aryl group, and Ar³ and Ar⁴ are each independently selected from the group consisting of a substituted or unsubstituted aromatic hydrocarbon group and a substituted or unsubstituted heterocyclic group, in case where the aromatic hydrocarbon group and the heterocyclic group are substituted, the substituent is selected from the group consisting of an alkyl group, a halogen atom, and a substituted amino group.

Further features of the present disclosure will become apparent from the following description of exemplary embodiments with reference to the attached drawings.

### BRIEF DESCRIPTION OF THE DRAWINGS

FIG. 1 is a cross-sectional frame format illustrating an example of an embodiment in an organic electroluminescence device.

FIGS. 2A to 2C are frame formats illustrating a light-emitting unit.

FIG. 3 is a diagram showing the absorption spectra of a sample A and a sample B.

### DESCRIPTION OF THE EMBODIMENTS

### First Embodiment

The present disclosure relates to an organic electroluminescence device having an anode, a cathode, and an organic compound layer which is disposed between the anode and the cathode and has a light-emitting layer and an organic functional layer. Thus, in an example embodiment, the organic compound layer disposed between a pair of electrodes containing the anode and the cathode is a laminate having at least two layers (the light-emitting layer, the organic functional layer). However, the layers contained in the organic compound layer are not limited only to the light-emitting layer and the organic functional layer. In an example embodiment, examples of layers contained in the organic compound layer include, in addition to the light-emitting layer and the organic functional layer, a hole injection layer, a hole transport layer, an electron blocking layer, a hole blocking layer, an electron transport layer, an electron injection layer, and the like.

In an example embodiment, the organic functional layer contains an organic compound represented by the following general formula (1) or (2) and a transition metal having a work function of 4.4 eV or more,

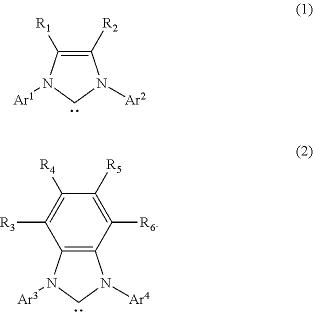

In Formula (1), R₁ and R₂ each independently represent a substituent selected from a hydrogen atom, a halogen atom, an alkyl group having carbon atoms of 1 or more and 8 or less, and an aryl group which may have a substituent.

Examples of the halogen atom represented by R₁ or R₂ include a fluorine atom, a chlorine atom, a bromine atom, an iodine atom, and the like and a fluorine atom is suitable.

Examples of the alkyl group having carbon atoms of 1 or more and 8 or less represented by R₁ or R₂ include a methyl group, an ethyl group, an n-propyl group, an isopropyl group, an n-butyl group, an iso-butyl group, a sec-butyl group, a tert-butyl group, an n-pentyl group, an n-hexyl group, an n-octyl group, and the like.

Examples of the aryl group represented by R₁ or R₂ include a phenyl group and the like. The aryl group may further have substituents, e.g., alkyl groups, such as a methyl group, an ethyl group, an n-propyl group, an isopropyl group, an n-butyl group, an iso-butyl group, a sec-butyl group, and a tert-butyl group, hydrocarbon aromatic ring groups, such as a phenyl group, a naphthyl group, a phenanthryl group, and a fluorenyl group, and halogen atoms, such as a fluorine atom, a chlorine atom, a bromine atom, and an iodine atom (suitably a fluorine atom).

In Formula (1), Ar¹ and Ar² each independently represent an aromatic hydrocarbon group which may have an alkyl group, a halogen atom, or a substituted amino group or a heterocyclic group which may have an alkyl group, a halogen atom, or a substituted amino group.

Examples of the aromatic hydrocarbon group represented by Ar¹ or Ar² include a phenyl group, a naphthyl group, an anthryl group, and the like. The aromatic hydrocarbon group is suitably a substituent selected from a phenyl group, a naphthyl group, and an anthryl group and particularly suitably a phenyl group.

Examples of the heterocyclic group represented by Ar¹ or Ar² include a pyridyl group, a bipyridyl group, a thiophenyl group, a carbazole group, and the like. The heterocyclic group is suitably a substituent selected from a pyridyl group, a bipyridyl group, a thiophenyl group, and a carbazole group and particularly suitably a pyridyl group.

Examples of the alkyl group which may be contained in the aromatic hydrocarbon group and the heterocyclic group include a methyl group, an ethyl group, a propyl group, an isopropyl group, an isobutyl group, a t-butyl group, and the like. Examples of the halogen atom which may be contained in the aromatic hydrocarbon group and the heterocyclic group include a fluorine atom, a chlorine atom, a bromine atom, an iodine atom, and the like.

Examples of the substituted amino group which may be contained in the aromatic hydrocarbon group and the heterocyclic group include alkylamino groups having C1 to C4 alkyl groups (for example, a dimethylamino group and the like), arylamino groups having a phenyl group, a naphthyl group, and the like (for example, a diphenylamino group and the like) and the like. The substituents contained in the substituted amino groups may be the same or different from each other.

In the aromatic hydrocarbon group and the heterocyclic group represented by Ar¹ or Ar², alkyl groups suitably substitute for two carbon atoms located on both sides of a carbon atom bonded to a nitrogen atom in the basic skeleton of the compound represented by General Formula (1), i.e., the carbon atoms located at both the ortho positions. In the aromatic hydrocarbon group represented by Ar¹ or Ar², examples of the substituents in which the alkyl groups substitute for the carbon atoms located at both the ortho positions include substituents represented by the following general formula (3), for example,

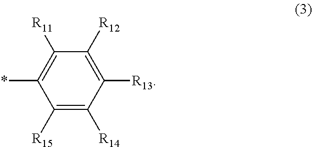

In Formula (3), * represents a bond with a nitrogen atom. In Formula (3), R₁₁ to R₁₅ each independently represent a hydrogen atom or an alkyl group. It is suitable that R₁₁ to R₁₅ each independently represent an alkyl group. Examples of the alkyl groups represented by R₁₁ to R₁₅ include a methyl group, an ethyl group, a propyl group, an isopropyl group, an isobutyl group, a t-butyl group, and the like. Specific examples of the substituents represented by General Formula (3) include a 2,6-diisopropylphenyl group, a mesityl group, and the like.

In Formula (2), R₃ to R₆ each independently represent a substituent selected from a hydrogen atom, a halogen atom, an alkyl group having carbon atoms of 1 or more and 8 or less, and an aryl group which may have a substituent. Specific examples of the halogen atom, the alkyl group, and the aryl group represented by any one of R₃ to R₆ are the same as the specific examples of the halogen atom, the alkyl group, and the aryl group represented by R₁ or R₂ in Formula (1). Specific examples of the substituents which may be contained in the aryl group are also the same as the specific examples of the alkyl group which may be contained in the aryl group represented by R₁ or R₂ in Formula (1).

In Formula (2), Ar³ and Ar⁴ each independently represent an aromatic hydrocarbon group which may have an alkyl group, a halogen atom, or a substituted amino group or a heterocyclic group which may have an alkyl group, a halogen atom, or a substituted amino group. Specific examples of the aromatic hydrocarbon group and the heterocyclic group represented by Ar³ or Ar⁴ are the same as the specific examples of the aromatic hydrocarbon group and the heterocyclic group represented by Ar³ or Ar⁴ in Formula (1). Specific examples of the alkyl group, the halogen atom, and the substituted amino group which may be contained in the aromatic hydrocarbon group and the heterocyclic group are also the same as the specific examples of the alkyl group, the halogen atom, and the substituted amino group which may be contained in the aromatic hydrocarbon group and the heterocyclic group represented by Ar¹ or Ar² in Formula (1).

Herein, the organic compounds represented by General Formula (1) and (2) are carbene compounds. The combination of the carbene compound and a transition metal can improve the electron injection efficiency of the organic electroluminescence device. The mechanism of the improvement of the electron injection efficiency is described later. Herein, the carbene refers to a carbon species which has six valence electrons and two electrons which are not involved in the bonding of carbon atoms. Therefore, compounds having the carbene have strong electron donation properties, and thus easily react with moisture or oxygen in the atmosphere. Therefore, the compounds having the carbene generally have low stability.

However, the carbene compounds represented by General Formulae (1) and (2) (hereinafter sometimes referred to as “a carbene compound (1)” and “a carbene compound (2),” respectively, as appropriate) are nitrogen-containing heterocyclic carbene skeletons having an imidazole structure with high aromatic properties. Therefore, the carbene compound (1) and the carbene compound (2) are materials having high stability among the carbene compounds. Among the carbene compound (1) and the carbene compound (2), when the substituents (Ar¹ to Ar⁴) bonded to the nitrogen atom in the basic skeleton are substituents having alkyl groups in the carbon atoms located at both the ortho positions, the alkyl groups contained in the substituents can further stabilize the carbene itself. Therefore, such compounds are particularly suitable.

Examples of the carbene compounds usable as constituent materials of the organic electroluminescence device of this application are shown below. However, the carbene compounds are not limited to the compounds of the example embodiment.

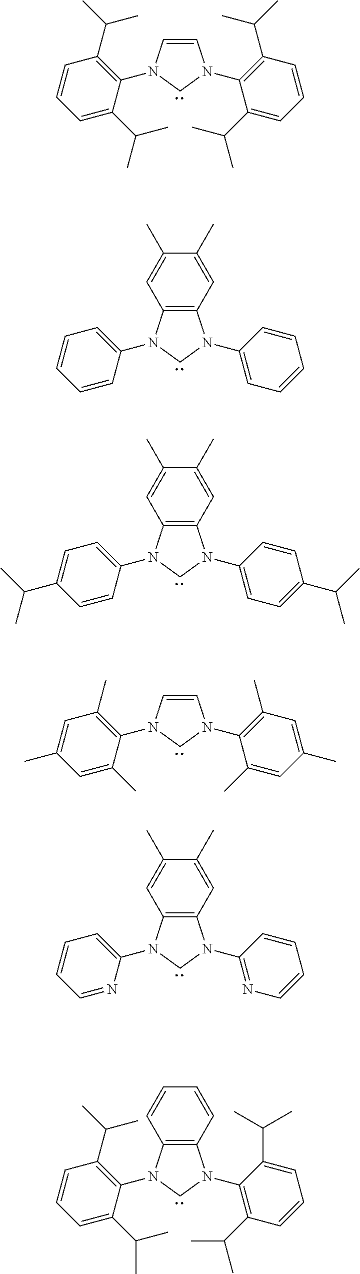

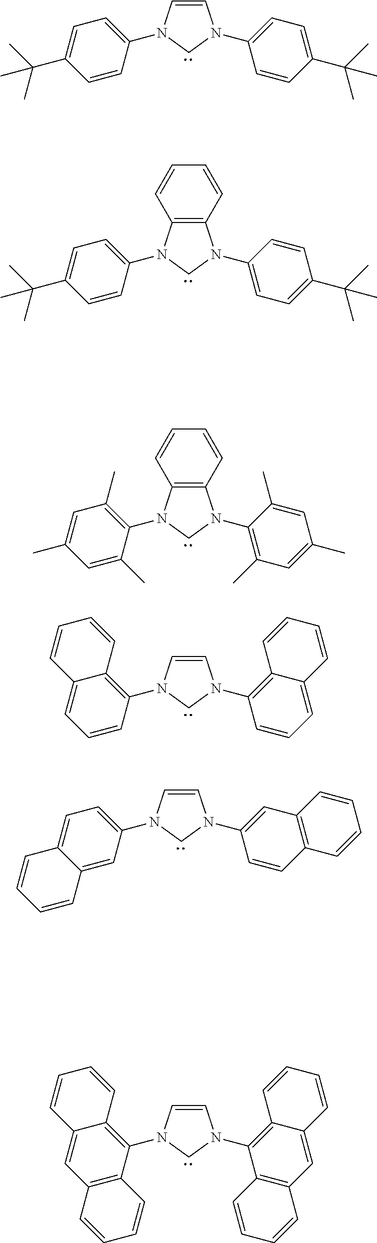

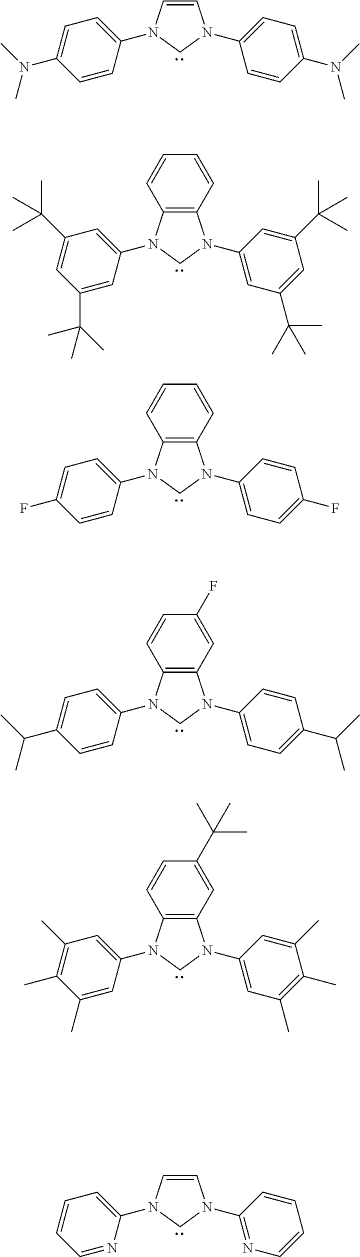

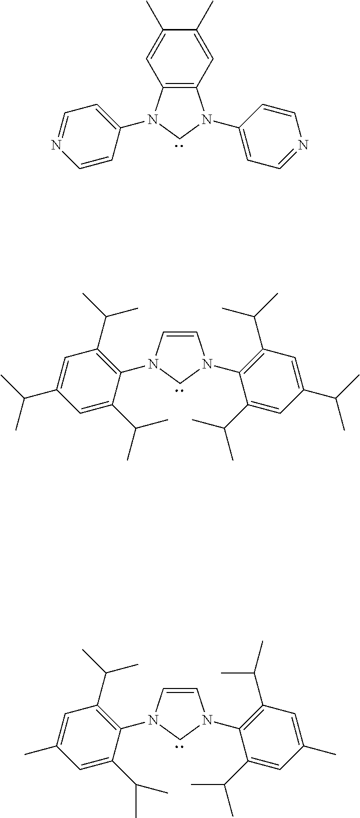

Examples of transition metals contained in the organic functional layer include metal materials having a work function as high as 4.4 eV or more. Among the metal materials, metal materials selected from Ag, Au, Cu, and Pt are suitable.

In an example embodiment, the metal materials having a work function of 4.4 eV or more are used with the carbene compound (1) or the carbene compound (2). This is because electrons supplied from a carbene complex are easily received, so that interactions become easy to cause. Ag, Au, Cu, and Pt are suitable because Ag, Au, Cu, and Pt are all transition metals and show plasmonic characteristics resulting from free electron vibration in metals so as to be expected to cause the following interactions.

In the organic functional layer, the carbene compound and the transition metal contact each other. In this state, due to high electron donation properties of the carbene compound, a ligand to metal charge transfer (LMCT)-like interaction and an interaction with plasmon of metal occur on the surface of the transition metal. The interactions form a stable and electronically active state in the organic functional layer. The organic functional layer may have at least the carbene compound and the transition metal in the layer and may further contain carbene derivatives (for example, a carbene precursor, a carbene dimer) other than the carbene compounds or organic compounds well-known or known in the technical field.

A method for forming the organic functional layer is not particularly limited and is suitably a method including forming the organic functional layer by codeposition of the carbene compound and the transition metal by a vacuum deposition method. In particular, by co-depositing the carbene compound (1) and the transition metal by a resistance heating deposition method in vacuum, a mixed film of the carbene compound (1) and the transition metal can be formed. In the mixed film, the transition metal is suitably present in a particle shape. The transition metal particles are not particularly limited in the shape of the particle itself insofar as the particles have localized surface plasmon and a size of about several nanometers to several tens of nanometers. Examples of specific shapes of the transition metal particles include a spherical shape, a rod shape, an island shape, a flake shape, and the like, for example. Thus, the transition metals are present in a particle shape in the organic functional layer. This is because vaporized metal atoms generated by deposition of the transition metal form a fine aggregate due to low wettability with organic compounds, such as the carbene compound.

When the transition metal to be used in the formation of the organic functional layer is an element which generates surface plasmon, such as silver and gold, it can be confirmed that the transition metal is present in a fine particle shape by confirming the surface plasmon.

The organic functional layer can be formed not only by dry methods, such as the vacuum deposition method, but by wet methods. In such a case, the carbene compound and the transition metal in a fine particle shape are dissolved and dispersed in a solvent. As specific methods for forming the organic functional layer by wet methods, a spin coat method, an ink jet method, a spray method, a casting method, a dipping method, and the like can be mentioned.

In an example embodiment, the film thickness of the organic functional layer is suitably 0.1 nm or more and more suitably in the range of 1 nm to 10 nm but is not particularly limited. The film thickness can be selected as appropriate according to the function of the organic electroluminescence device itself. The concentration of the transition metal to be mixed in the organic functional layer based on the entire organic functional layer is not particularly limited insofar as the carbene compound and the transition metal are contained in the layer. It is suitable to increase the ratio of the carbene compound to be higher in order to more certainly cause the interactions. For example, the concentration of the transition metal based on the entire organic functional layer is suitably 0.1% by volume or more and 50% by volume or less and more suitably 1% by volume to 10% by volume. As the concentration of the transition metal based on the entire organic functional layer, the optimal concentration can be selected as appropriate according to the type of the carbene compounds and the transition metals contained in the layer.

### Second Embodiment

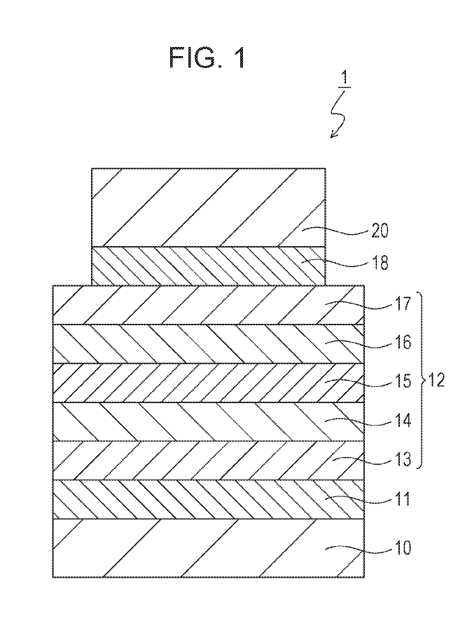

FIG. 1 is a cross-sectional frame format illustrating an example of an embodiment in an organic electroluminescence device.

An organic electroluminescence device 1 of FIG. 1 has a cathode 11 formed on a substrate 10, an organic compound layer 12 provided on the cathode 11, and an anode 18 provided on the organic compound layer 12. The organic compound layer 12 configuring the organic electroluminescence device 1 of FIG. 1 is a laminate in which an organic functional layer 13, an electron transport layer 14, a light-emitting layer 15, a hole transport layer 16, and a hole injection layer 17 are stacked in order from the substrate 10 side. The organic electroluminescence device 1 of FIG. 1 has a capping layer 20 provided on the anode 18. Although the organic electroluminescence device 1 of FIG. 1 has the cathode 11 as an electrode on the side of the substrate 10, the anode 18 may be used as an electrode on the side of the substrate 10 in an example embodiment. When the anode 18 is an electrode on the side of the substrate 10, the stacking order in the organic compound layer 12 may be an order of a hole injection layer, a hole transport layer, a light-emitting layer, an electron transport layer, and an organic functional layer from the substrate 10 side, for example.

Hereinafter, the case where the cathode 11 is an electrode on the side of the substrate 10 as illustrated in FIG. 1 is described. The configuration illustrated in FIG. 1 is one example of the configuration of an organic electroluminescence device, and the present invention is not limited to the configuration.

The substrate 10 is a member to be used as a support of the organic electroluminescence device 1. Examples of constituent materials of the substrate 10 include glass, plastic, metal materials, and the like, for example. When the substrate 10 is transparent, light emission of the organic electroluminescence device 1 can be extracted from the substrate 10 side.

As constituent materials of the cathode 11 and the anode 18, transparent oxide conductors, such as indium tin oxide and indium zinc oxide, metal materials, such as aluminum (Al), silver (Ag), silicon (Si), titanium (Ti), tungsten (W), and molybdenum (Mo), alloys obtained by combining two or more kinds of these metal materials, metallic compounds, such as titanium nitride (TiN), and the like can be mentioned. Moreover, composite materials obtained by combining two or more kinds of these materials mentioned above can also be used. In the organic electroluminescence device 1 of FIG. 1, the cathode 12 which is an electrode of the substrate 10 may contain a single layer or may contain a plurality of layers. In the organic electroluminescence device of an example embodiment, the organic functional layer 13 is a layer having high electron injection properties. Therefore, constituent materials of the cathode 11 are not limited to materials having a small work function and materials having a large work function can also be used.

When light output from the light-emitting layer 15 is extracted from the substrate 10 side, members which transmit light are used for the substrate 10 and the cathode 11 and a member which is opaque or reflects light is used for the anode 18. On the other hand, when light output from the light-emitting layer 15 is extracted from the side opposite to the substrate 10, a member which is opaque or reflects light is used for the cathode 11 and a member which transmits light is used for the anode 18.

The light-emitting layer 15 is a layer containing a substance having high light emission properties. In the formation of the light-emitting layer 15, the light-emitting layer 15 may be formed using only a substance having high light emission properties but it is suitable to form the light-emitting layer 15 in an aspect of doping a small amount of a substance having high light emission properties into a host material. Examples of the host material include triarylamine derivatives, phenylene derivatives, condensed ring aromatic compounds (for example, a naphthalene derivative, a phenanthrene derivative, a fluorene derivative, a chrysene derivative, a perylene derivative, and the like), organic metal complexes (for example, organic aluminum complexes, such as tris(8-quinolinolate)aluminum, an organic beryllium complex, an organic iridium complex, an organic platinum complex, and the like), polymer derivatives, such as a poly(phenylene vinylene) derivative, a poly(fluorene) derivative, a poly(phenylene) derivative, a poly(thienylene vinylene) derivative, and a poly(acetylene) derivative but the host material is not limited thereto. Examples of the substance having high light emission properties include, for example, triarylamine derivatives, phenylene derivatives, condensed ring aromatic compounds (for example, a fluoranthene derivative, a benzofluoranthene derivative, a pyrene derivative, a chrysene derivative, diarylamine substituted derivatives thereof, and the like), blue, green, and red light-emitting fluorescent materials, such as stilbene derivatives, and blue, green, and red light-emitting phosphorescent materials, such as organic metal complexes (for example, an organic iridium complex, an organic platinum complex, a rare earth metal complex, and the like). The substances having high light emission properties are contained in a proportion of suitably 0.1% by volume or more and 30% by volume or less and more suitably 0.5% by volume or more and 10% by volume or less based on the entire light-emitting layer 15.

The hole transport layer 16 is a layer which transports holes injected from the anode 18 to the light-emitting layer 15. As constituent materials of the hole transport layer 16, arylamine derivatives, carbazole derivatives, and the like having a benzidine skeleton can be used.

The hole injection layer 17 is a layer for efficiently injecting holes into the light-emitting layer 15 from the anode 18. A layer having conductivity increased by compounding a hole transport material and an electron extraction material, such as p-dopants, is suitably used. As p-dopant materials, transition metal oxides, such as molybdenum oxide and tungsten oxide, and organic p-dopants, such as a hexaazatriphenylene derivative and a tetracyanoquinodimethane, can be used.

The electron transport layer 14 is a layer for efficiently transporting electrons injected from the organic functional layer 13 to the light-emitting layer 15. Electron transport materials serving as constituent materials of the electron transport layer 14 are selected as appropriate considering the balance with the hole mobility of the hole injection material or the hole transport material and the like. Examples of the electron transport materials include condensed ring aromatic compounds (for example, a naphthalene derivative, a phenanthrene derivative, a fluorene derivative, and a chrysene derivative), an oxadiazole derivative, an oxazole derivative, a pyrazine derivative, a triazole derivative, a triazine derivative, a quinoline derivative, a quinoxaline derivative, a phenanthroline derivative, an organic aluminum complex, and the like. It is a matter of course that the electron transport materials are not limited thereto.

Although not illustrated in the organic electroluminescence device 1 of FIG. 1, a hole blocking layer may be provided as appropriate between the electron transport layer 14 and the light-emitting layer 15 and an electron blocking layer may be provided as appropriate between the hole transport layer 16 and the light-emitting layer 15. The electron transport layer 14 may contain a single layer or may have a stacked configuration having a plurality of layers. When the electron transport layer 14 has a stacked configuration, a layer contacting the cathode 11 may be used as the electron injection layer.

The capping layer 20 can be used as a sealing film which seals the organic electroluminescence device 1. The capping layer 20 can be used as an optical interference layer when extracting light, which is output from the light-emitting layer 15, from the anode 18. Examples of constituent materials of the capping layer 20 include inorganic materials, such as silicon oxide, silicon nitride, indium tin oxide, and indium zinc oxide, and organic materials, for example. The film thickness of the capping layer 20 may be set as appropriate according to the intended use. When the capping layer 20 is used as a sealing film, the film thickness is suitably 100 nm or more and 10 μm or less. When the capping layer 20 is used as a sealing film, it is suitable that the capping layer 20 is a layer containing a single layer or two or more layers containing inorganic materials, such as silicon nitride, silicon oxide, silicon oxynitride, and aluminum oxide. On the other hand, when the capping layer 20 is used as an optical interference layer, the film thickness is suitably 50 nm or more and 300 nm or less. However, in an example embodiment, the capping layer 20 may not be necessarily provided. As described above, the organic electroluminescence device 1 may be sealed only with a sealing film containing the capping layer 20 or may be sealed by covering the organic electroluminescence device 1 with glass, metal, or the like.

When the organic electroluminescence device according to this embodiment is fabricated, layers can be generally formed by a vacuum deposition method, an ionization deposition method, a sputtering method, or plasma deposition or by known coating methods (for example, spin coating, dipping, a cast method, an LB method, an ink jet method, and the like) using a solution in a suitable solvent.

### Third Embodiment

The organic functional layer contained in the organic electroluminescence device can be used as a charge generation layer. When the organic functional layer is used as a charge generation layer, the organic functional layer can be used in the following stacked configuration, for example.

The stacked configuration is as follows: Substrate/Cathode/First electron transport layer/First light-emitting layer/First hole transport layer/Hole injection layer/Organic functional layer/Second electron transport layer/Second light-emitting layer/Second hole transport layer/Anode.

In the stacked configuration described above, the configuration in which the first electron transport layer, the first light-emitting layer, and the first hole transport layer are successively stacked is equivalent to the configuration of the organic compound layer which is one member of the organic electroluminescence device. Similarly, the configuration in which the second electron transport layer, the second light-emitting layer, and the second hole transport layer, are successively stacked is also equivalent to the configuration of the organic compound layer.

Constituent materials of the electron transport layers (the first electron transport layer, the second electron transport layer), the light-emitting layers (the first light-emitting layer, the second light-emitting layer), and the hole transport layers (the first hole transport layer, the second hole transport layer) contained in the configuration described above may be the same or different from each other. The light emission colors of the two kinds of light-emitting layers (the first light-emitting layer, the second light-emitting layer) contained in the configuration may be the same or different from each other. In the stacked configuration of this embodiment, the organic functional layer is the same as the organic functional layer contained in the organic electroluminescence device of the first embodiment and extracts electrons from the hole injection layer, and then transports the electrons to the second electron transport layer. In the hole injection layer from which the electrons are extracted, holes are generated. Therefore, the organic functional layer indirectly transports holes from the hole injection layer to the first hole transport layer. The extraction of electrons from an adjacent layer (hole injection layer) by the organic functional layer is a function peculiar to the organic functional layer and is a function possessed by the organic functional layer even when the organic functional layer does not contact an electrode. For the hole injection layer contained in the stacked configuration of this embodiment, the hole injection layer 17 contained in the organic electroluminescence device according to the second embodiment can be used, for example.

### Intended Use of Organic Electroluminescence Device

The organic electroluminescence device can be used as a constituent member of a display apparatus or a lighting apparatus. In addition thereto, the organic electroluminescence device can be applied to an exposure light source of an electro-photography type image formation apparatus, a back light of a liquid crystal apparatus, lighting, and the like. The organic electroluminescence device may further have a color filter.

In a display apparatus of an example embodiment, the organic electroluminescence device may be contained in a display section having a plurality of pixels. Each pixel has the organic electroluminescence device and an active element. As one example of the active element, a switching element for controlling the emitted luminance is mentioned. As one example of the switching element, a TFT element is mentioned. In the display apparatus of the example embodiment, the anode or the cathode of the organic electroluminescence device contained in the pixel is connected to a drain electrode or a source electrode of the TFT element provided on an insulating surface of a substrate configuring the display apparatus. The display apparatus can be used as an image display apparatus of a personal computer (PC).

The display apparatus may be an image information processing apparatus having an input section which inputs image information from an area CCD, a linear CCD, and a memory card and which displays an input image on a display section. The display section provided in the image information processing apparatus and the image formation apparatus may have a touch panel function. The display apparatus may be used for a display section of a multifunction printer.

A lighting apparatus of an example embodiment is an apparatus which illuminates the interior of a room, for example. The lighting apparatus may emit light of any wavelength of a white color, a daytime white color, a blue color, or a red color. The organic electroluminescence device provided in the lighting apparatus has a plurality of light-emitting materials in the organic compound layer, particularly in the light-emitting layer, and at least any one of the light-emitting materials emits light of a color different from that of the other light-emitting materials. By extracting light emitted from these light-emitting materials to the outside, illumination light can be obtained. The illumination light is suitably a white color.

The lighting apparatus has the organic electroluminescence device and an AC/DC converter circuit connected thereto. In an example embodiment, the lighting apparatus may have a color filter. The AC/DC converter circuit contained in the lighting apparatus of is a circuit which converts an alternating voltage to a direct current voltage and is a circuit for supplying a driving voltage to the organic electroluminescence device.

An image formation apparatus of an example embodiment has a photoconductor, an exposure section for exposing the photoconductor, and a developer section supplying a developing agent to the photoconductor. In the image formation apparatus of the, the developer section has a developer for developing an electrostatic latent image formed on the surface of the photoconductor. In the example embodiment, the image formation apparatus may further have a charging section which charges the surface of the photoconductor, for example. In the image formation apparatus, an exposure means has the organic electroluminescence device. Examples of the exposure means configuring the image formation apparatus include an exposing machine having the organic electroluminescence devices, for example. The organic electroluminescence devices provided in the exposing machine may be disposed to form an array or have an aspect in which light is emitted from the entire exposure surface of the exposing machine. When the organic electroluminescence devices provided in the exposing machine are disposed to form an array, the plurality of organic electroluminescence device are desirably disposed along the direction of the rotation axis of the photoconductor.

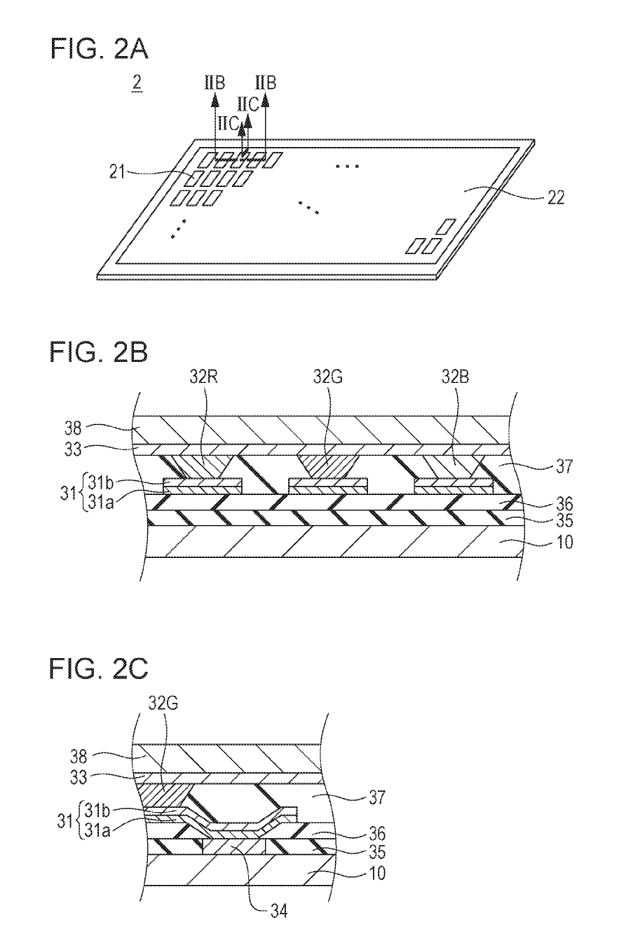

Hereinafter, example embodiments of the light-emitting unit are described with reference to the drawings. FIGS. 2A to 2C are frame formats illustrating the example light-emitting unit. FIG. 2A is a perspective diagram, FIG. 2B is a cross-sectional view illustrating the cross section along the IIB-IIB line in FIG. 2A, and FIG. 2C is a cross-sectional view illustrating the cross section along the IIC-IIC line in FIG. 2A. A light-emitting unit of FIGS. 2A to 2C can be used as a display apparatus. The light-emitting unit 2 of FIGS. 2A to 2C has a plurality of pixels 21 each having an organic electroluminescence device. In the light-emitting unit 2 of FIGS. 2A to 2C, the pixels 21 are disposed in a matrix pattern and form a light-emitting region 22. The region where the pixels 21 are provided illustrated in FIG. 2A is a region corresponding to a light-emitting region corresponding to one light-emitting element. Since the light-emitting element of the light-emitting unit is an organic electroluminescence device, the light-emitting unit is a light-emitting unit in which an organic electroluminescence device, which outputs light of a predetermined light emission color, is disposed in each pixel 21. Examples of the light emission color of the organic electroluminescence devices include a red color, a green color, and a blue color, for example. However, the light emission color is not limited thereto and a white color, a yellow color, a cyan color, and the like may be acceptable. In the light-emitting unit of the example embodiment, a plurality of pixel units containing a plurality kinds of pixels different in the light emission color (for example, a pixel which emits a red color light, a pixel which emits a green color light, and a pixel which emits a blue color light) may be arranged. Herein, the pixel unit refers to the minimum unit which allows light emission of a desired color by mixing the color of each pixel. In the light-emitting unit of the example embodiment, an arrangement aspect of the pixels 21 may be the matrix arrangement as illustrated in FIG. 2A, for example, or may be an aspect in which a plurality of pixels emitting light of the same color are arranged in the one-dimensional direction in order to use the same as a light-emitting unit for print heads may be acceptable.

As illustrated in FIG. 2B, the plurality of pixels 21 configuring the light-emitting unit 2 each have an organic electroluminescence device having, on a substrate 10, a first electrode 31 which is an electrode on the side of the substrate 10, an organic compound layer (32R, 32G, or 32B) containing a light-emitting layer, and a second electrode 33, in this order. The organic electroluminescence device provided in the light-emitting unit 2 of FIGS. 2A to 2C has a configuration in which a reflection surface reflecting light, which is emitted from the light-emitting layer and travels to the first electrode 31, is provided in the first electrode 31 and in which light is extracted from the second electrode 33.

In the light-emitting unit 2 of FIGS. 2A to 2C, a transistor 34 for supplying a current to the organic electroluminescence device is disposed between the substrate 10 and the first electrode 31 and is connected to the first electrode 31 as illustrated in FIG. 2C. More specifically, the first electrode 31 is connected to a source electrode or a drain electrode of the transistor 34. On the transistor 34, a first insulating layer 35 and a second insulating layer 36 are formed so as to cover at least one part of the transistor 34. In the first insulating layer 35 and the second insulating layer 36, an opening is formed in at least one part of a region where the transistor 34 is provided. In the opening, the first electrode 31 and the transistor 34 are connected to each other. A third insulating layer 37 is formed so as to cover at least the opening.

In the light-emitting unit 2 of FIGS. 2A to 2C, the first electrode 31 is a stacked electrode in which a first layer 31a and a second layer 31b are stacked in this order. As constituent materials of the first layer 31a, metal materials having high reflectivity, such as Al, Al alloys, such as AlNd, and Ag alloys, can be used. The film thickness of the first layer 31a may be 50 nm or more and 200 nm or less. The first layer 31a is connected to the transistor 34 and has a function of a cathode which supplies electrons to the organic electroluminescence device and a function of a reflective layer for extracting light output in the organic compound layers (32R, 32G, 32B) provided in the organic electroluminescence device to the second electrode 33 side. Examples of constituent materials of the second layer 31b include metal materials having a high work function (for example, metal materials, such as Mo and W), oxides (for example, indium tin oxide, indium zinc oxide, and the like), and the like. However, in an example embodiment, when the first electrode 31 is provided, the formation of the second layer 31b may be omitted. When light output in the organic compound layers (32R, 32G, 32B) is extracted from the substrate 10 side, transparent conductive oxides, such as indium tin oxide and indium zinc oxide, can be used as constituent materials of the first layer 31a.

In the light-emitting unit 2 of FIGS. 2A to 2C, the substrate 10 contains a glass substrate, a semiconductor substrate, a metal substrate, or the like, and a flexible substrate can also be used, for example.

In the light-emitting unit 2 of FIGS. 2A to 2C, the transistor 34 may be formed with semiconductors, such as polysilicon and amorphous silicon.

As constituent materials of the first insulating layer 35, inorganic insulation materials, such as silicon nitride, silicon oxide, and silicon oxynitride, can be used. The film thickness of the first insulating layer 35 may be 100 nm or more and 1 μm or less. The first insulating layer 35 may also be used as the second insulating layer 36.

As constituent materials of the second insulating layer 36, resin materials, such as polyimide resin and acrylic resin, inorganic materials, such as silicon nitride, and the like can be used. In particular, when not only the first insulating layer 35 but the second insulating layer 36 is formed, the second insulating layer 36 may contain resin materials for the purpose of leveling unevenness of the surface of the transistor 34. When the second insulating layer 36 is formed using inorganic materials, the surface may be polished so that the surface of the second insulating layer 36 may be flat. When the second insulating layer 36 is formed with resin materials, the film thickness of the second insulating layer 36 is suitably 300 nm or more and 10 μm or less. On the other hand, when the second insulating layer 36 is formed with inorganic materials, the film thickness of the second insulating layer 36 is suitably 100 nm or more and 1 μm or less.

The third insulating layer 37 can be formed with the same materials as those of the second insulating layer 36 and can be formed with the same film thickness. The third insulating layer 37 may be not necessarily provided in the case of a configuration in which the first electrode 31 and the second electrode 33 do not short circuit, for example, a configuration in which the organic compound layers (32R, 32G, 32B) cover up to the side surface of the first electrode 31. The third insulating layer 37 may be provided on the transistor 34 but may be not necessarily provided on the transistor 34.

The organic compound layers (32R, 32G, 32B) configuring the light-emitting unit 2 of FIGS. 2A to 2C have a multilayer stacked configuration containing a plurality of layers containing at least the organic functional layer and the light-emitting layer which emits light of a red color, a green color, or a blue color described in the first to third embodiments. The organic functional layer contained in the organic compound layer has high electron injection efficiency. Therefore, the driving voltage of the organic electroluminescence device can be reduced and the light emission efficiency can be increased. The organic compound layers (32R, 32G, 32B) each have any one of a light-emitting layer which emits a red color light, a light-emitting layer which emits a green color light, or a light-emitting layer which emits a blue color light. Each light-emitting layer is pattern-formed corresponding to a pixel (organic electroluminescence device) which emits light of any one of a red color, a green color, or a blue color. The organic compound layers (32R, 32G, 32B) each may have one or two or more layers of a hole transport layer and an electron transport layer in addition to the organic functional layer and the light-emitting layer. The hole transport layer or the electron transport layer may be formed corresponding to the pixel (organic electroluminescence device) or may be formed across the plurality of pixels, or the combination of the configurations may be acceptable.

The first electrode 31 is separated from the first electrode 31 provided in the organic electroluminescence device configuring the next pixel and is formed in each pixel (organic electroluminescence device). The second electrode 33 may be formed as an electrode which is shared by the next pixel or may be pattern-formed in each pixel. As illustrated in FIG. 2B, an aspect is suitable in which the third insulating layer 37 covers end portions of the first electrode 31 so that the first electrode 31 and the second electrode 33 do not short circuit.

The light-emitting unit may be provided with an optical adjustment layer 38 containing organic materials or inorganic materials on the second electrode 33 as illustrated in FIG. 2B. When the optical adjustment layer 38 is provided, the optical interference effect can be increased by adjusting the film thickness, so that the light emission efficiency of the organic electroluminescence device can be further increased. The organic electroluminescence device configuring the light-emitting unit 2 of FIGS. 2A to 2C is sealed with sealing glass (not illustrated) in order to prevent entering of moisture or oxygen.

The light-emitting unit can be applied to image formation apparatuses, such as a laser beam printer. More specifically, the image formation apparatus has a photoconductor on which a latent image is formed by the light-emitting unit and a charging means which charges the photoconductor. The light-emitting unit may contain a plurality of organic electroluminescence devices which emit different colors. In such a case, the light-emitting unit can be used as a display or an electronic view finder of imaging devices, such as a digital camera and a digital video camera having image pickup elements, such as a CMOS sensor. In addition thereto, the light-emitting unit can be used as a display of image formation apparatuses and a display of personal digital assistants, such as a cellular phone and a smartphone. The light-emitting unit may have a configuration of having a plurality of monochromatic organic electroluminescence devices and red, green, and blue color filters.

### EXAMPLES

Hereinafter, an example embodiment of the organic electroluminescence device is more specifically described with reference to Examples.

### Film Characteristics of Organic Functional Layer

The film characteristics of the organic functional layer provided in the organic electroluminescence device are evaluated by methods described below.

A glass substrate was cleaned by UV treatment, and then the glass substrate was placed in a vacuum chamber. Next, the degree of vacuum in the vacuum chamber was set to 10⁻⁴ Pa, and then a compound 10 shown below which is a carbene compound and silver (Ag) were co-deposited on the glass substrate by a vacuum deposition method employing resistance heating.

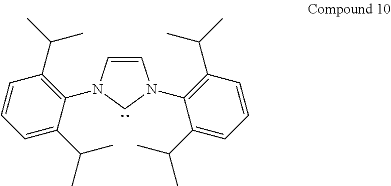

In this process, the film thickness of the co-deposited film was set to 11 nm and the deposition speed was adjusted so that the volume ratio of the compound 10 to the silver (Ag) contained in the co-deposited film was Compound 10:Ag=10:1. Herein, a substrate on which the co-deposited film was formed is used as a sample A. On the other hand, a substrate on which only the compound 10 was formed into a film with a film thickness of 10 nm under the same conditions as the vacuum conditions described above is used as a sample B. Next, with respect to the sample A and the sample B, the films formed on the substrate were sealed by bonding a sealing glass containing a desiccant and the film formation surface of the glass substrate to each other using an epoxy resin adhesive in a glovebox in a nitrogen atmosphere.

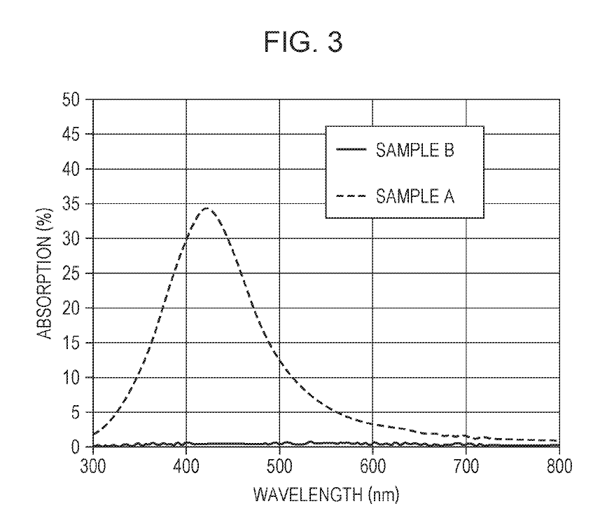

Next, the penetration reflectivity of the fabricated samples was measured with a spectrophotometer (SolidSpec 3700, manufactured by Shimadzu Corporation), and then the absorption spectra were calculated. FIG. 3 is a diagram showing the absorption spectrum of each of the sample A and the sample B. From FIG. 3, characteristic plasmon absorption by silver fine particles was observed in the co-deposited film of the compound 10 and Ag, and therefore it was confirmed that the Ag contained in the co-deposited film was mixed in the form of fine particles in the film.

### Example 1

Some materials used for this example are shown below.

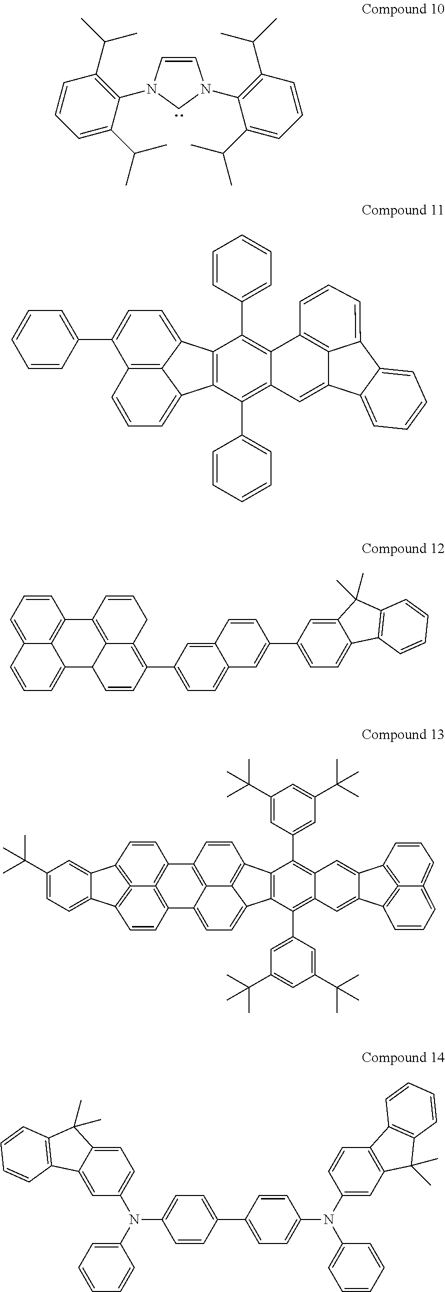

Indium tin oxide (ITO) was formed into a film on a glass substrate by sputtering to form a cathode. In this process, the film thickness of the cathode was set to 120 nm. Next, the substrate on which the cathode was formed was successively ultrasonically cleaned with acetone and isopropyl alcohol (IPA), and then cleaned by boiling in IPA, followed by drying. The resultant substrate was further cleaned with UV/ozone to be used as a transparent conductive support substrate in the following process. Next, the transparent conductive support substrate was placed in a vacuum chamber, and then the degree of vacuum in the vacuum chamber was set to 10⁻⁴ Pa. Next, layers described below were formed in order on the cathode by a vacuum deposition method employing resistance heating. First, the compound 10 (carbene compound) and Ag (transition metal) were co-deposited to form an organic functional layer. In this example, a plurality of kinds of organic functional layers were formed as shown in the following Table 1 by adjusting the deposition speed and the film thickness as appropriate. In all the samples (1a to 1d), the organic functional layers were electronically active.

TABLE 1

| | Compound 10:Ag | Film thickness |
|---|---|---|
| | (Volume ratio) | [nm] |
| Sample 1a | 10:0.5 | 3.1 |
| Sample 1b | 10:1 | 3.3 |
| Sample 1c | 10:3 | 3.9 |
| Sample 1d | 10:5 | 4.5 |

Next, the compound 11 was formed into a film to form an electron transport layer having a film thickness of 40 nm on the organic functional layer. Next, the compound 12 and the compound 13 were co-deposited to form a light-emitting layer having a film thickness of 20 nm on the electron transport layer. In this process, the deposition speed was adjusted so that the concentration of the compound 13 was 0.5% by volume based on the entire light-emitting layer. Next, the compound 14 was formed into a film to form a hole transport layer having a film thickness of 30 nm on the light-emitting layer. Next, the compound 14 and molybdenum trioxide were co-deposited to form a hole injection layer having a film thickness of 20 nm on the hole transport layer. In this process, the deposition speed was adjusted so that the concentration of the molybdenum trioxide was 5% by volume based on the entire hole injection layer. Next, Ag was formed into a film to form an anode having a film thickness of 100 nm on the hole injection layer. Thus, an organic electroluminescence device was obtained. The organic electroluminescence device was sealed in the following process by bonding a sealing glass containing a desiccant and the film formation surface of the glass substrate to each other using an epoxy resin adhesive in a glovebox in a nitrogen atmosphere. With respect to the obtained organic electroluminescence device, the voltage and the luminance characteristics in the application of a fixed current were measured and evaluated. Herein, the current efficiency (cd/A) and the voltage (V) at a current density of 100 mA/cm² are shown in the following Table 2.

### Example 2

A film having a film thickness of 3.3 nm was formed by using gold (Au) in place of Ag and adjusting the deposition speed so that the volume ratio of the compound 10 and the Au was Compound 10:Au=10:1 (volume ratio) in the formation of the organic functional layer in Example 1. Except the changes above, an organic electroluminescence device was obtained by the same method as that of Example 1. The obtained organic electroluminescence device was evaluated and measured for the voltage and the luminance characteristics in the application of a fixed current by the same method as that of Example 1. Herein, the current efficiency (cd/A) and the voltage (V) at a current density of 100 mA/cm² are shown in the following Table 2.

### Example 3

A film having a film thickness of 3.3 nm was formed by adjusting the deposition speed so that the volume ratio of the compound 10, the compound 11, and Ag was Compound 10:Compound 11:Ag=5:5:1 (volume ratio) in the formation of the organic functional layer in Example 1. Except the change above, an organic electroluminescence device was obtained by the same method as that of Example 1. The obtained organic electroluminescence device was evaluated and measured for the voltage and the luminance characteristics in the application of a fixed current by the same method as that of Example 1. Herein, the current efficiency (cd/A) and the voltage (V) at a current density of 100 mA/cm² are shown in the following Table 2.

### Example 4

A hole injection layer was formed by a method described below before forming the organic functional layer in Example 2.

### Formation of Hole Injection Layer

A transparent conductive support substrate was placed in a vacuum chamber, and then the degree of vacuum in the vacuum chamber was set to 10⁻⁴ Pa. Next, the compound 14 and molybdenum trioxide were co-deposited to form a hole injection layer having a film thickness of 10 nm on a cathode by a vacuum deposition method employing resistance heating. The deposition speed was adjusted so that the concentration of the molybdenum oxide based on the entire hole injection layer was 5% by volume in the formation of the hole injection layer.

Except the changes above, an organic electroluminescence device was obtained by the same method as that of Example 2. The obtained organic electroluminescence device was evaluated and measured for the voltage and the luminance characteristics in the application of a fixed current by the same method as that of Example 1. Herein, the current efficiency (cd/A) and the voltage (V) at a current density of 100 mA/cm² are shown in the following Table 2.

### Example 5

Indium tin oxide (ITO) was formed into a film on a glass substrate by sputtering to form an anode. In this process, the film thickness of the anode was set to 120 nm. Next, the substrate on which the anode was formed was successively ultrasonically cleaned with acetone and isopropyl alcohol (IPA), and then cleaned by boiling in IPA, followed by drying. The resultant substrate was further cleaned with UV/ozone to be used as a transparent conductive support substrate in the following process. Next, the transparent conductive support substrate was placed in a vacuum chamber, and then the degree of vacuum in the vacuum chamber was set to 10⁻⁴ Pa. Next, layers described below were formed in order on the anode by a vacuum deposition method utilizing resistance heating. First, the compound 14 and molybdenum trioxide were co-deposited to form a hole injection layer having a film thickness of 20 nm on the hole transport layer. In this process, the deposition speed was adjusted so that the concentration of the molybdenum oxide based on the entire hole injection layer was 5% by volume. Next, the compound 14 was formed into a film to form a hole transport layer having a film thickness of 30 nm on the hole injection layer. Next, the compound 12 and the compound 13 were co-deposited to form a light-emitting layer having a film thickness of 20 nm on the hole injection layer. In this process, the deposition speed was adjusted so that the concentration of the compound 13 based on the entire light-emitting layer was 0.5% by volume. Next, the compound 11 was formed into a film to form an electron transport layer having a film thickness of 40 nm on the light-emitting layer. Next, the compound 10 (carbene compound) and Ag (transition metal) were co-deposited to form an organic functional layer having a film thickness of 3.3 nm on the electron transport layer. In this process, the deposition speed was adjusted so that the volume ratio of the compound 10 and the Ag was Compound 10:Ag=10:1. Next, Al was formed into a film to form a cathode having a film thickness of 100 nm on the organic functional layer. Thus, an organic electroluminescence device was obtained. The organic electroluminescence device was sealed in the following process by bonding a sealing glass containing a desiccant and the film formation surface of the glass substrate to each other using an epoxy resin adhesive in a glovebox in a nitrogen atmosphere. The obtained organic electroluminescence device was evaluated and measured for the voltage and the luminance characteristics in the application of a fixed current by the same method as that of Example 1. Herein, the current efficiency (cd/A) and the voltage (V) at a current density of 100 mA/cm² are shown in the following Table 2.

### Example 6

A film having a film thickness of 3.3 nm was formed by using the compound 20 in place of the compound 10 and adjusting the deposition speed so that the volume ratio of the compound 20 and Ag was Compound 20:Ag=10:1 (volume ratio) in the formation of the organic functional layer in Example 1. Except the changes above, an organic electroluminescence device was obtained by the same method as that of Example 1. The obtained organic electroluminescence device was evaluated and measured for the voltage and the luminance characteristics in the application of a fixed current by the same method as that of Example 1. Herein, the current efficiency (cd/A) and the voltage (V) at a current density of 100 mA/cm² are shown in the following Table 2.

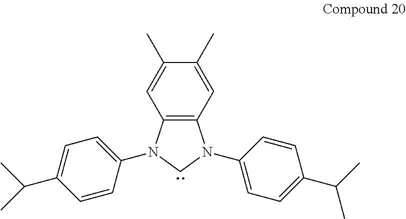

### Comparative Example 1

An organic electroluminescence device was obtained by the same method as that of Example 1, except forming only the compound 10 into a film to form an organic functional layer having a film thickness of 3 nm in Example 1. The obtained organic electroluminescence device was evaluated and measured for the voltage and the luminance characteristics in the application of a fixed current by the same method as that of Example 1. Herein, the current efficiency (cd/A) and the voltage (V) at a current density of 100 mA/cm² are shown in the following Table 2.

### Comparative Example 2

An organic electroluminescence device was obtained by the same method as that of Example 2, except using aluminum (Al) in place of Ag in Example 2. The obtained organic electroluminescence device was evaluated and measured for the voltage and the luminance characteristics in the application of a fixed current by the same method as that of Example 1. Herein, the current efficiency (cd/A) and the voltage (V) at a current density of 100 mA/cm² are shown in the following Table 2.

TABLE 2

| | | | Current efficiency (*1) |
|---|---|---|---|
| Voltage (*1) [V] | | | [cd/A] |
| Example 1 | Sample 1a | 5.2 | 4.7 |
| | Sample 1b | 5.4 | 4.5 |
| | Sample 1c | 5.7 | 4.2 |
| | Sample 1d | 5.8 | 3.9 |

| | | |
|---|---|---|
| Ex. 2 | 5.0 | 4.7 |
| Ex. 3 | 5.3 | 4.6 |
| Ex. 4 | 5.9 | 4.4 |
| Ex. 5 | 3.4 | 4.4 |
| Ex. 6 | 5.9 | 4.4 |
| Comp. Ex. 1 | 8.7 | 0.5 |
| Comp. Ex. 2 | 8.0 | 2.1 |

(*1): at 100 mA/cm²

Table 2 showed that the use of the organic functional layer as a layer configuring an organic electroluminescence device increases the function of the organic electroluminescence device in terms of the driving voltage and the efficiency. Moreover, Example 4 showed that the organic functional layer can be functioned as a charge generation layer. As described above, it was shown that the use of the organic compound layer can improve the characteristics relating to charges of the organic electroluminescence device, such as electron injection/transport characteristics.

The present disclosure can provide an organic electroluminescence device which is driven at a low voltage and has a long life.

While the present disclosure has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2015-240722, filed Dec. 10, 2015, which is hereby incorporated by reference herein in its entirety.

What is claimed is:

1. An organic electroluminescence device comprising:
an anode;
a cathode; and
an organic compound layer disposed between the anode and the cathode, wherein
the organic compound layer contains a light-emitting layer and an organic functional layer, and
the organic functional layer contains an organic compound represented by General Formula (1) or (2) and a transition metal having a work function of 4.4 eV or more, 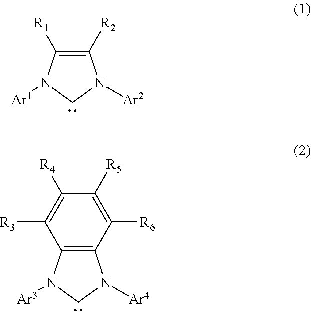
wherein, in Formula (1), R₁ and R₂ are each independently selected from the group consisting of a hydrogen atom, a halogen atom, an alkyl group having carbon atoms of 1 or more and 8 or less, and a substituted or unsubstituted aryl group, and Ar¹ and Ar² are each independently selected from the group consisting of a substituted or unsubstituted aromatic hydrocarbon group and a substituted or un substituted heterocyclic group, in case where the aromatic hydrocarbon group and the heterocyclic group are substituted, the substituent is selected from the group consisting of an alkyl group, a halogen atom, and a substituted amino group,
wherein, in Formula (2), R₃ to R₆ are each independently selected from the group consisting of a hydrogen atom, a halogen atom, an alkyl group having carbon atoms of 1 or more and 8 or less, and a substituted or unsubstituted aryl group, and Ar³ and Ar⁴ are each independently selected from the group consisting of a substituted or unsubstituted aromatic hydrocarbon group and a substituted or unsubstituted heterocyclic group, in case where the aromatic hydrocarbon group and the heterocyclic group are substituted, the substituent is selected from the group consisting of an alkyl group, a halogen atom, and a substituted amino group.

2. The organic electroluminescence device according to claim 1, wherein
the aromatic hydrocarbon group is selected from the group consisting of a phenyl group, a naphthyl group, and an anthryl group, and
the heterocyclic group is selected from the group consisting of a pyridyl group, a bipyridyl group, a thiophenyl group, and a carbazole group.

3. The organic electroluminescence device according to claim 1, wherein
the aromatic hydrocarbon group is a phenyl group, and
the heterocyclic group is a pyridyl group.

4. The organic electroluminescence device according to claim 1, wherein
the aromatic hydrocarbon group is a substituent represented by General Formula (3) shown below, 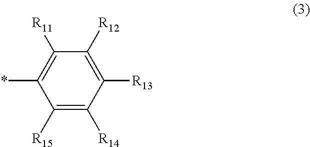
wherein, in Formula (3), * represents a bond with a nitrogen atom, and R¹¹ to R¹⁵ each independently represent a hydrogen atom or an alkyl group.

5. The organic electroluminescence device according to claim 1, wherein
the transition metal is selected from the group consisting of Ag, Au, Pt, and Cu.

6. The organic electroluminescence device according to claim 1, wherein
when an entire organic functional layer is 100% by volume, a concentration of the transition metal is 0.1% by volume or more and 50% by volume or less.

7. The organic electroluminescence device according to claim 1, wherein
the organic functional layer contacts the anode or the cathode.

8. The organic electroluminescence device according to claim 1, wherein
a thickness of the organic functional layer is 1 nm to 10 nm.

9. A display apparatus comprising:
a plurality of pixels, wherein
at least one of the plurality of pixels contains the organic electroluminescence device according to claim 1 and an active element connected to the organic electroluminescence device.

10. A lighting apparatus comprising:
the organic electroluminescence device according to claim 1; and
an AC/DC converter connected to the organic electroluminescence device.

11. An image formation apparatus comprising:
a photoconductor;
an exposure section exposing the photoconductor; and
a developer section supplying a developing agent to the photoconductor, wherein:
the exposure section contains two or more of the organic electroluminescence device according to claim 1, and
the two or more of the organic electroluminescence devices are arranged along a direction of a rotation axis of the photoconductor.
